(19) United States
(12) Patent Application Publication
(10) Pub. No.: US 2025/0180627 A1
(43) Pub. Date: Jun. 5, 2025

(54) SEMICONDUCTOR TEST APPARATUS

(71) Applicant: ROHM CO., LTD., Kyoto-shi (JP)

(72) Inventor: Satoru KOMINAMI, Kyoto-shi (JP)

(73) Assignee: ROHM CO., LTD., Kyoto-shi (JP)

(21) Appl. No.: 19/044,833

(22) Filed: Feb. 4, 2025

Related U.S. Application Data
(63) Continuation of application No. PCT/JP2023/025536, filed on Jul. 11, 2023.

(30) Foreign Application Priority Data
Aug. 4, 2022 (JP) 2022-124695

(51) Int. Cl. G01R 31/26; G01R 31/52

(52) U.S. Cl. CPC G01R 31/2621; G01R 31/2608; G01R 31/52

(57) ABSTRACT

A semiconductor test apparatus includes first and second node portions for connecting a semiconductor switching device. It features a high-voltage, low-current power supply and a low-voltage, high-current power supply. A first relay, rated for the high voltage, connects the first node to the high-voltage supply. A second relay, rated for the low voltage, connects the first node to the low-voltage supply. A third relay, rated for high voltage, is in parallel with the second relay, while a fourth relay, rated for low voltage, is in parallel with the low-voltage supply.

### CROSS-REFERENCE TO RELATED APPLICATIONS

The present application is a bypass continuation of International Patent Application No. PCT/JP2023/025536, filed on Jul. 11, 2023, which claims priority to Japanese Patent Application No. 2022-124695 filed in the Japan Patent Office on Aug. 4, 2022, and those entire disclosures of the applications are incorporated herein by reference.

### BACKGROUND

### 1. Field of the Disclosure

The present disclosure relates to a semiconductor test apparatus.

### 2. Description of the Related Art

JP2010-107432A discloses a semiconductor test apparatus that performs a thermal resistance test, a surge test, a switching characteristic test, and a continuous operation test of a power semiconductor element. JP2012-229971A discloses a semiconductor inspection apparatus that inspects a switching characteristic (dynamic characteristic) and a saturation voltage (static characteristic) of a power semiconductor element.

### BRIEF DESCRIPTION OF THE DRAWINGS

FIG. 1 is a circuit diagram showing an electrical arrangement of a semiconductor test apparatus according to an embodiment.

FIG. 2 is a circuit diagram showing a circuit operation of the semiconductor test apparatus during a high-voltage/low-current test.

FIG. 3 is a circuit diagram showing a circuit operation of the semiconductor test apparatus during a low-voltage/high-current test.

FIG. 4 is a plan view of a semiconductor rectifier shown in FIG. 1.

FIG. 5 is a sectional view taken along line V-V shown in FIG. 4.

FIG. 6 is a plan view showing an example of a semiconductor switching device (tested device).

FIG. 7 is a sectional view taken along line VII-VII shown in FIG. 6.

FIG. 8 is a plan view showing an internal arrangement of the semiconductor switching device shown in FIG. 6.

FIG. 9 is a sectional view taken along line IX-IX shown in FIG. 8.

### DETAILED DESCRIPTION OF THE PREFERRED EMBODIMENTS

Hereinafter, an embodiment shall be described in detail with reference to attached drawings. The attached drawings are schematic views and are not strictly illustrated, and scales and the like thereof do not always match. Also, identical reference signs are given to corresponding structures among the attached drawings, and duplicate descriptions thereof shall be omitted or simplified. For the structures whose description have been omitted or simplified, the description given before the omission or simplification shall apply.

When the wording “substantially equal” is used in a description in which a comparison target is present, the wording includes a numerical value (shape) equal to a numerical value (shape) of the comparison target and also includes numerical errors (shape errors) in a range of ±10% on a basis of the numerical value (shape) of the comparison target. Although the wordings “first,” “second,” “third,” etc., are used with the embodiments, these are symbols attached to names of respective structures in order to clarify the order of description and are not attached with an intention of restricting the names of the respective structures.

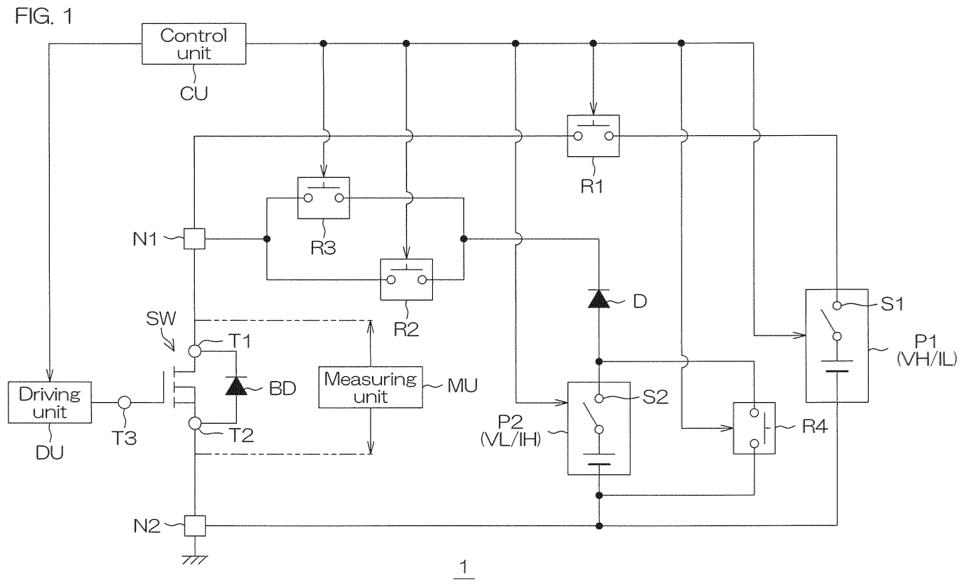

FIG. 1 is a circuit diagram showing an electrical arrangement of a semiconductor test apparatus 1 according to an embodiment. The semiconductor test apparatus 1 is an apparatus that tests electrical characteristics of a semiconductor switching device SW as a tested device. The semiconductor test apparatus 1 may also be referred to as a “characteristic test apparatus” or a “semiconductor inspection apparatus.”

The semiconductor switching device SW is a semiconductor device that includes a transistor. The semiconductor switching device SW may include at least one among a MISFET (metal insulator semiconductor field effect transistor), an IGBT (insulated gate bipolar transistor), and a BJT (bipolar junction transistor).

The semiconductor switching device SW may have an Si-transistor that includes an Si (silicon) monocrystal. The semiconductor switching device SW preferably has a wide bandgap semiconductor transistor that includes a monocrystal of a wide bandgap semiconductor. The wide bandgap semiconductor is a semiconductor that has a greater bandgap than the bandgap of Si. GaN (gallium nitride), SiC (silicon carbide), C (diamond), etc., can be cited as examples of the wide bandgap semiconductor.

The semiconductor switching device SW especially preferably has an SiC transistor that includes an SiC (silicon carbide) monocrystal as an example of the wide bandgap semiconductor. In this embodiment, the semiconductor switching device SW is an SiC-MISFET (field effect transistor). The semiconductor switching device SW may include a planar gate type transistor or may include a trench gate type transistor.

The semiconductor switching device SW is preferably a power semiconductor switching device (power transistor) that has a first breakdown voltage VB1 of not less than 500 V. The first breakdown voltage VB1 may be not more than 3000 V.

The first breakdown voltage VB1 may have a value belonging to any one range among not less than 500 V and not more than 750 V, not less than 750 V and not more than 1000 V, not less than 1000 V and not more than 1250 V, not less than 1250 V and not more than 1500 V, not less than 1500 V and not more than 1750 V, not less than 1750 V and not more than 2000 V, not less than 2000 V and not more than 2250 V, not less than 2250 V and not more than 2500 V, not less than 2500 V and not more than 2750 V, and not less than 2750 V and not more than 3000 V.

The semiconductor switching device SW includes a first terminal T1 (one end), a second terminal T2 (other end), and a control terminal T3 (control end). The first terminal T1, the second terminal T2, and the control terminal T3 are a drain terminal, a source terminal, and a gate terminal of the MISFET in this embodiment. When the semiconductor switching device SW includes an IGBT, the first terminal T1, the second terminal T2, and the control terminal T3 are a collector terminal, an emitter terminal, and a gate terminal of the IGBT. When the semiconductor switching device SW includes a BJT, the first terminal T1, the second terminal T2, and the control terminal T3 are a collector terminal, an emitter terminal, and a base terminal of the BJT.

In this embodiment, the semiconductor switching device SW includes a body diode BD that is electrically connected to the first terminal T1 and the second terminal T2. The body diode BD includes an anode that is electrically connected to the second terminal T2 and a cathode that is electrically connected to the first terminal T1.

The semiconductor test apparatus 1 includes a first node portion N1 (high potential application end) at one side (high potential side) and a second node portion N2 (low potential application end) at another side (low potential side). The second node portion N2 is connected to a ground potential (for example, zero potential) in this embodiment. The first terminal T1 of the semiconductor switching device SW is to be electrically connected to the first node portion N1. The second terminal T2 of the semiconductor switching device SW is to be electrically connected to the second node portion N2. The first node portion N1 and the second node portion N2 are open ends at times other than during testing and are to be electrically connected to the first terminal T1 and the second terminal T2 of the semiconductor switching device SW during testing.

The semiconductor test apparatus 1 includes a first power supply P1 for high-voltage/low-current test that generates a comparatively high first voltage VH and a comparatively low first current IL. The first power supply P1 is arranged, in consideration of safety, such as not to cause a high voltage and high current state. The first power supply P1 has a first power supply switch S1 and is arranged to be switchable between an on state and an off state. The first power supply P1 has a positive electrode at the first node portion N1 side and a negative electrode at the second node portion N2 side.

The first power supply P1 applies the first voltage VH and the first current IL to the first node portion N1 when the first power supply switch S1 is on. That is, the first power supply P1 applies the first voltage VH and the first current IL to the first terminal T1 of the semiconductor switching device SW. In the high-voltage/low-current test, a leak current Ioff is measured as an off current that flows through the semiconductor switching device SW in a state in which a high voltage is applied to the semiconductor switching device SW in the off state.

The first voltage VH is preferably lower than the first breakdown voltage VB1 of the semiconductor switching device SW. The first voltage VH may be not less than 500 V. The first voltage VH may be not more than 3000 V.

The first voltage VH may have a value belonging to any one range among not less than 500 V and not more than 750 V, not less than 750 V and not more than 1000 V, not less than 1000 V and not more than 1250 V, not less than 1250 V and not more than 1500 V, not less than 1500 V and not more than 1750 V, not less than 1750 V and not more than 2000 V, not less than 2000 V and not more than 2250 V, not less than 2250 V and not more than 2500 V, not less than 2500 V and not more than 2750 V, and not less than 2750 V and not more than 3000 V.

The first current IL is not more than 1 A. The first current IL is preferably less than 1 A. The first current IL is especially preferably not less than 0.01 mA and not more than 100 mA. The first current IL may have a value belonging to any one range among not less than 0.01 mA and not more than 0.05 mA, not less than 0.05 mA and not more than 0.1 mA, not less than 0.1 mA and not more than 0.5 mA, not less than 0.5 mA and not more than 1 mA, not less than 1 mA and not more than 5 mA, not less than 5 mA and not more than 10 mA, not less than 10 mA and not more than 25 mA, not less than 25 mA and not more than 50 mA, not less than 50 mA and not more than 75 mA, and not less than 75 mA and not more than 100 mA. The first current IL is preferably not less than 0.1 mA and not more than 5 mA.

The semiconductor test apparatus 1 includes a second power supply P2 for low-voltage/high-current test that generates a comparatively low second voltage VL and a comparatively high second current IH. Specifically, the second voltage VL is lower than the first voltage VH and the second current IH is higher than the first current IL. The second power supply P2 is arranged, in consideration of safety, such as not to cause a high voltage and high current state. The second power supply P2 has a second power supply switch S2 and is arranged to be switchable between an on state and an off state. The second power supply P2 has a positive electrode at the first node portion N1 side and a negative electrode at the second node portion N2 side.

The second power supply P2 applies the second voltage VL and the second current IH to the first node portion N1 when the second power supply switch S2 is on. That is, the second power supply P2 applies the second voltage VL and the second current IH to the first terminal T1 of the semiconductor switching device SW. In the low-voltage/high-current test, an on resistance Ron of the semiconductor switching device SW is measured in a state in which a high current is applied to the semiconductor switching device SW in the on state.

The second voltage VL may be not more than 100 V. The second voltage VL may be not less than 0.1 V. The second voltage VL may have a value belonging to any one range among not less than 0.1 V and not more than 1 V, not less than 1 V and not more than 5 V, not less than 5 V and not more than 10 V, not less than 10 V and not more than 25 V, not less than 25 V and not more than 50 V, not less than 50 V and not more than 75 V, and not less than 75 V and not more than 100 V.

The second current IH may be not less than 1 A. The second current IH is preferably greater than 1 A. The second current IH may be not more than 100 A. The second current IH may have a value belonging to any one range among not less than 1 A and not more than 5 A, not less than 5 A and not more than 10 A, not less than 10 A and not more than 25 A, not less than 25 A and not more than 50 A, not less than 50 A and not more than 75 A, and not less than 75 A and not more than 100 A. The second current IH is especially preferably not less than 10 A and not more than 75 A.

The semiconductor test apparatus 1 includes a first relay R1 that is electrically interposed between the first node portion N1 and the first power supply P1. The first relay R1 may, for example, be an electromagnetic relay that includes an electromagnetic coil (electromagnet) and a contact (electromagnetic contact). The first relay R1 is constituted of a high-withstand-voltage/low-current type relay capable of withstanding a load due to the first power supply P1. That is, as with the first power supply P1, the first relay R1 is arranged, in consideration of safety, such as not to cause a high voltage and high current state.

The first relay R1 is arranged such as to switch between a conducting state (on state) of electrically connecting the first power supply P1 to the first node portion N1 and a nonconducting state (off state) of electrically opening the first power supply P1 from the first node portion N1. In the conducting state of the first relay R1, the first voltage VH and the first current IL of the first power supply P1 are to be applied to the semiconductor switching device SW via the first node portion N1. In the nonconducting state of the first relay R1, the first voltage VH and the first current IL of the first power supply P1 are interrupted.

The first relay R1 has a first withstand voltage of not less than the first voltage VH of the first power supply P1. Failure of the first relay R1 due to a voltage load of the first power supply P1 is thereby suppressed. The first withstand voltage is preferably greater than the first voltage VH. The first withstand voltage may be not less than 1 times and not more than 100 times the first voltage VH. The first withstand voltage is preferably not more than 10 times the first voltage VH. The first withstand voltage may be not less than 500 V and not more than 3000 V.

The first withstand voltage may have a value belonging to any one range among not less than 500 V and not more than 750V, not less than 750 V and not more than 1000V, not less than 1000 V and not more than 1250V, not less than 1250 V and not more than 1500V, not less than 1500 V and not more than 1750V, not less than 1750 V and not more than 2000V, not less than 2000 V and not more than 2250V, not less than 2250 V and not more than 2500V, not less than 2500 V and not more than 2750V, and not less than 2750 V and not more than 3000V.

The first relay R1 has a first rated energizing current of not less than the first current IL of the first power supply P1. Failure of the first relay R1 due to a current load of the first power supply P1 is thereby suppressed. The first rated energizing current is preferably greater than the first current IL.

The first rated energizing current may be not less than 1 times and not more than 100 times the first current IL. The first rated energizing current is preferably not more than 10 times the first current IL. The first rated energizing current may be not more than 1 A. The first rated energizing current is preferably less than 1 A. The first rated energizing current is especially preferably not less than 0.01 mA and not more than 100 mA.

The first rated energizing current may have a value belonging to any one range among not less than 0.01 mA and not more than 0.05 mA, not less than 0.05 mA and not more than 0.1 mA, not less than 0.1 mA and not more than 0.5 mA, not less than 0.5 mA and not more than 1 mA, not less than 1 mA and not more than 5 mA, not less than 5 mA and not more than 10 mA, not less than 10 mA and not more than 25 mA, not less than 25 mA and not more than 50 mA, not less than 50 mA and not more than 75 mA, and not less than 75 mA and not more than 100 mA. The first rated energizing current may be not less than 1 mA. The first rated energizing current may be not more than 5 mA.

The semiconductor test apparatus 1 includes a second relay R2 that is electrically interposed between the first node portion N1 and the second power supply P2. The second relay R2 may, for example, be an electromagnetic relay that includes an electromagnetic coil (electromagnet) and a contact (electromagnetic contact). The second relay R2 is constituted of a low-withstand-voltage/high-current type relay capable of withstanding a load due to the second power supply P2. That is, as with the second power supply P2, the second relay R2 is arranged, in consideration of safety, such as not to cause a high voltage and high current state.

The second relay R2 is arranged such as to switch between a conducting state (on state) of electrically connecting the second power supply P2 to the first node portion N1 and a nonconducting state (off state) of electrically opening the second power supply P2 from the first node portion N1. In the conducting state of the second relay R2, the second voltage VL and the second current IH of the second power supply P2 are to be applied to the semiconductor switching device SW via the first node portion N1. In the nonconducting state of the second relay R2, the second voltage VL and the second current IH of the second power supply P2 are interrupted.

The second relay R2 has a second withstand voltage of not less than the second voltage VL of the second power supply P2. Failure of the second relay R2 due to a voltage load of the second power supply P2 is thereby suppressed. The second withstand voltage is preferably greater than the second voltage VL. The second withstand voltage may be not more than the first voltage VH of the first power supply P1 (the first withstand voltage of the first relay R1). The second withstand voltage may be less than the first voltage VH of the first power supply P1 (the first withstand voltage of the first relay R1).

The second withstand voltage may be not less than 1 times and not more than 100 times the second voltage VL. The second withstand voltage is preferably not more than 10 times the second voltage VL. The second withstand voltage may be not less than 0.1 V and not more than 100 V. The second withstand voltage may have a value belonging to any one range among not less than 0.1 V and not more than 1 V, not less than 1 V and not more than 5 V, not less than 5 V and not more than 10 V, not less than 10 V and not more than 25 V, not less than 25 V and not more than 50 V, not less than 50 V and not more than 75 V, and not less than 75 V and not more than 100 V. The second withstand voltage is preferably not less than 1 V. The second withstand voltage is especially preferably not less than 10 V.

The second relay R2 has a second rated energizing current of not less than the second current IH of the second power supply P2. Failure of the second relay R2 due to a current load of the second power supply P2 is thereby suppressed. The second rated energizing current is preferably greater than the second current IH. The second rated energizing current may be not less than 1 times and not more than 100 times the second current IH. The second rated energizing current is preferably not more than 10 times the second current IH.

The second rated energizing current may be not less than 1 A and not more than 200 A. The second rated energizing current is preferably greater than 1 A. The second rated energizing current may have a value belonging to any one range among not less than 1 A and not more than 5 A, not less than 5 A and not more than 10 A, not less than 10 A and not more than 25 A, not less than 25 A and not more than 50 A, not less than 50 A and not more than 75 A, not less than 75 A and not more than 100 A, not less than 100 A and not more than 125 A, not less than 125 A and not more than 150 A, not less than 150 A and not more than 175 A, and not less than 175 A and not more than 200 A. The second rated energizing current is preferably not less than 10 A.

The semiconductor test apparatus 1 includes a third relay R3 that is connected in parallel to the second relay R2. The third relay R3 may, for example, be an electromagnetic relay that includes an electromagnetic coil (electromagnet) and a contact (electromagnetic contact). The third relay R3 is constituted of a high-withstand-voltage/low-current type relay capable of withstanding the load due to the first power supply P1. That is, as with the first power supply P1, the third relay R3 is arranged, in consideration of safety, such as not to cause a high voltage and high current state.

The third relay R3 is arranged such as to switch between a conducting state (on state) of short-circuiting the second relay R2 and a nonconducting state (off state) of not short-circuiting the second relay R2. The third relay R3 has a third withstand voltage of not less than the second voltage VL of the second power supply P2. That is, the third withstand voltage is not less than the second withstand voltage of the second relay R2. Failure of the third relay R3 due to the voltage load of the second power supply P2 is thereby suppressed. The third withstand voltage is especially preferably greater than the second voltage VL of the second power supply P2 (the second withstand voltage of the second relay R2).

In this embodiment, the third relay R3 short-circuits the second relay R2 to fix a voltage across terminals of the second relay R2 at zero voltage and protects the second relay R2 from the voltage load due to the first voltage VH of the first power supply P1. The third withstand voltage is thus not less than the first voltage VH of the first power supply P1. Failure of the third relay R3 due to the voltage load of the first power supply P1 is thereby suppressed. The third withstand voltage is preferably greater than the first voltage VH.

The third withstand voltage may be not less than 1 times and not more than 100 times the first voltage VH. The third withstand voltage is preferably not more than 10 times the first voltage VH. The third withstand voltage may be not less than 500 V and not more than 3000 V.

The third withstand voltage may have a value belonging to any one range among not less than 500 V and not more than 750V, not less than 750 V and not more than 1000V, not less than 1000 V and not more than 1250V, not less than 1250 V and not more than 1500V, not less than 1500 V and not more than 1750V, not less than 1750 V and not more than 2000V, not less than 2000 V and not more than 2250V, not less than 2250 V and not more than 2500V, not less than 2500 V and not more than 2750V, and not less than 2750 V and not more than 3000V.

The third withstand voltage may be not less than the first withstand voltage of the first relay R1. The third withstand voltage may be less than the first withstand voltage. The third withstand voltage may be substantially equal to the first withstand voltage. In this case, the third relay R3 may be constituted of the same type of relay as the first relay R1.

The third relay R3 has a third rated energizing current of not less than the first current IL of the first power supply P1. Failure of the third relay R3 due to the current load of the first power supply P1 is thereby suppressed. The third rated energizing current is preferably greater than the first current IL. The third rated energizing current is less than the second current IH of the second power supply P2.

The third rated energizing current may be not less than 1 times and not more than 100 times the first current IL. The third rated energizing current is preferably not more than 10 times the first current IL. The third rated energizing current is especially preferably not more than 2 times the first current IL. The third rated energizing current may be not more than 1 A. The third rated energizing current is preferably less than 1 A. The third rated energizing current is especially preferably not less than 0.01 mA and not more than 100 mA.

The third rated energizing current may have a value belonging to any one range among not less than 0.01 mA and not more than 0.05 mA, not less than 0.05 mA and not more than 0.1 mA, not less than 0.1 mA and not more than 0.5 mA, not less than 0.5 mA and not more than 1 mA, not less than 1 mA and not more than 5 mA, not less than 5 mA and not more than 10 mA, not less than 10 mA and not more than 25 mA, not less than 25 mA and not more than 50 mA, not less than 50 mA and not more than 75 mA, and not less than 75 mA and not more than 100 mA. The third rated energizing current may be not less than 1 mA. The third rated energizing current may be not more than 5 mA.

The semiconductor test apparatus 1 includes a fourth relay R4 that is connected in parallel to the second power supply P2. The fourth relay R4 may, for example, be an electromagnetic relay that includes an electromagnetic coil (electromagnet) and a contact (electromagnetic contact). The fourth relay R4 is constituted of a low-withstand-voltage/high-current type relay capable of withstanding the load due to the second power supply P2. That is, as with the second power supply P2, the fourth relay R4 is arranged, in consideration of safety, such as not to cause a high voltage and high current state.

The fourth relay R4 is arranged such as to switch between a conducting state (on state) of short-circuiting the second power supply P2 and a nonconducting state (off state) of not short-circuiting the second power supply P2. The fourth relay R4 has a fourth withstand voltage of not less than the second voltage VL of the second power supply P2. Failure of the fourth relay R4 due to the voltage load of the second power supply P2 is thereby suppressed. The fourth withstand voltage is preferably greater than the second voltage VL. The fourth withstand voltage may be not more than the first voltage VH of the first power supply P1 (the first withstand voltage of the first relay R1). The fourth withstand voltage may be less than the first voltage VH of the first power supply P1 (the first withstand voltage of the first relay R1).

The fourth withstand voltage may be not less than 1 times and not more than 100 times the second voltage VL. The fourth withstand voltage is preferably not more than 10 times the second voltage VL. The fourth withstand voltage may be not less than 0.1 V and not more than 100 V. The fourth withstand voltage may have a value belonging to any one range among not less than 0.1 V and not more than 1 V, not less than 1 V and not more than 5 V, not less than 5 V and not more than 10 V, not less than 10 V and not more than 25 V, not less than 25 V and not more than 50 V, not less than 50 V and not more than 75 V, and not less than 75 V and not more than 100 V. The fourth withstand voltage is preferably not less than 1 V. The fourth withstand voltage is especially preferably not less than 10 V.

The fourth withstand voltage may be not less than the second withstand voltage of the second relay R2. The fourth withstand voltage may be less than the second withstand voltage. The fourth withstand voltage may be substantially equal to the second withstand voltage. In this case, the fourth relay R4 may be constituted of the same type of relay as the second relay R2.

The fourth relay R4 has a fourth rated energizing current of not less than the first current IL of the first power supply P1. The fourth rated energizing current is greater than the first current IL. The fourth rated energizing current is preferably not less than the second current IH of the second power supply P2. Failure of the fourth relay R4 due to the current load of the second power supply P2 is thereby suppressed. The fourth rated energizing current is especially preferably greater than the second current IH.

The fourth rated energizing current may be not less than 1 times and not more than 100 times the second current IH. The fourth rated energizing current is preferably not more than 10 times the second current IH. The fourth rated energizing current may be not less than 500 mA and not more than 200 A.

The fourth rated energizing current may have a value belonging to any one range among not less than 500 mA and not more than 1A, not less than 1 A and not more than 5 A, not less than 5 A and not more than 10 A, not less than 10 A and not more than 25 A, not less than 25 A and not more than 50 A, not less than 50 A and not more than 75 A, not less than 75 A and not more than 100 A, not less than 100 A and not more than 125 A, not less than 125 A and not more than 150 A, not less than 150 A and not more than 175 A, and not less than 175 A and not more than 200 A. The fourth rated energizing current may be not less than 1A. The fourth rated energizing current may be greater than 1A. The fourth rated energizing current is preferably not more than 10 A.

The semiconductor test apparatus 1 includes a semiconductor rectifier D that is electrically interposed between the first node portion N1 and the second power supply P2. The semiconductor rectifier D may be referred to as a “rectifier,” a “diode,” or a “protective diode.” The semiconductor rectifier D may include at least one among pn junction diode, a pin junction diode, a Schottky barrier diode, and a fast recovery diode.

The semiconductor rectifier D may have an Si diode that includes an Si monocrystal. The semiconductor rectifier D preferably has a wide bandgap semiconductor diode that includes a monocrystal of a wide bandgap semiconductor. The semiconductor rectifier D especially preferably has an SiC diode that includes an SiC monocrystal. In this embodiment, the semiconductor rectifier D includes an SiC-Schottky barrier diode.

The semiconductor rectifier D has a second breakdown voltage VB2 that is not less than the second voltage VL of the second power supply P2. The second breakdown voltage VB2 is preferably greater than the second voltage VL. The second breakdown voltage VB2 is preferably not less than the first voltage VH of the first power supply P1. The second breakdown voltage VB2 is especially preferably greater than the first voltage VH.

The second breakdown voltage VB2 is preferably not less than the first breakdown voltage VB1 of the semiconductor switching device SW. The second breakdown voltage VB2 may be greater than the first breakdown voltage VB1. The second breakdown voltage VB2 may be not less than 500 V. The second breakdown voltage VB2 may be not more than 3000 V.

The second breakdown voltage VB2 may have a value belonging to any one range among not less than 500 V and not more than 750V, not less than 750 V and not more than 1000V, not less than 1000 V and not more than 1250V, not less than 1250 V and not more than 1500V, not less than 1500 V and not more than 1750V, not less than 1750 V and not more than 2000V, not less than 2000 V and not more than 2250V, not less than 2250 V and not more than 2500V, not less than 2500 V and not more than 2750V, and not less than 2750 V and not more than 3000V.

The semiconductor rectifier D is electrically interposed between the second relay R2 and the second power supply P2. The semiconductor rectifier D is interposed in a direction of being in reverse bias with respect to a voltage application direction of the first power supply P1. Specifically, the semiconductor rectifier D includes an anode that is electrically connected to the second power supply P2 and a cathode that is electrically connected to the second relay R2. From another perspective, in the semiconductor rectifier D, the anode is electrically connected to the fourth relay R4 and the cathode is electrically connected to the third relay R3.

The semiconductor test apparatus 1 includes a measuring unit MU that is electrically connected to the semiconductor switching device SW. The measuring unit MU includes, for example, an ammeter that measures a current flowing through the semiconductor switching device SW and a voltmeter that measures a voltage across terminals of the semiconductor switching device SW.

The ammeter suffices to be incorporated at a location enabling measurement of the semiconductor switching device SW. For example, the ammeter may be electrically interposed between the first node portion N1 and the first terminal T1 of the semiconductor switching device SW. For example, the ammeter may be electrically interposed between the second node portion N2 and the second terminal T2 of the semiconductor switching device SW.

The voltmeter suffices to be incorporated at a location enabling measurement of the voltage across terminals of the semiconductor switching device SW. For example, the voltmeter may be connected between the first node portion N1 and the second node portion N2 (that is, between the first terminal T1 and the second terminal T2 of the semiconductor switching device SW). The measuring unit MU may be arranged such as to measure a resistance value (the on resistance Ron) based on the voltage across terminals and the current.

The semiconductor test apparatus 1 includes a driving unit DU that is to be electrically connected to the control terminal T3 of the semiconductor switching device SW. The driving unit DU includes a drive IC (gate driver circuit). The driving unit DU generates control signals that control on/off of the semiconductor switching device SW and outputs it to the control terminal T3 of the semiconductor switching device SW. The control signals include an on signal that controls the semiconductor switching device SW to be in an on state and an off signal that controls the semiconductor switching device SW to be in an off state.

The semiconductor test apparatus 1 includes a control unit CU that is electrically connected to the first power supply P1, the second power supply P2, the first relay R1, the second relay R2, the third relay R3, the fourth relay R4, the driving unit DU, and the measuring unit MU. The control unit CU includes, for example, a CPU, a memory (for example, a ROM, a RAM, a nonvolatile memory, etc.) and an electronic circuit and is arranged such as to control the first power supply P1, the second power supply P2, the first relay R1, the second relay R2, the third relay R3, the fourth relay R4, the driving unit DU, and the measuring unit MU based on a predetermined program (recipe) stored in the memory.

The control unit CU is arranged such as to control the semiconductor switching device SW to be in the off state, control the first power supply P1 to be in the on state, control the second power supply P2 to be in the off state, control the first relay R1 to be in the conducting state, control the second relay R2 to be in the nonconducting state, control the third relay R3 to be in the conducting state, and control the fourth relay R4 to be in the conducting state when performing the high-voltage/low-current test.

The control unit CU is arranged such as to control the semiconductor switching device SW to be in the on state, control the first power supply P1 to be in the off state, control the second power supply P2 to be in the on state, control the first relay R1 to be in the nonconducting state, control the second relay R2 to be in the conducting state, control the third relay R3 to be in the nonconducting state, and control the fourth relay R4 to be in the nonconducting state when performing the low-voltage/high-current test.

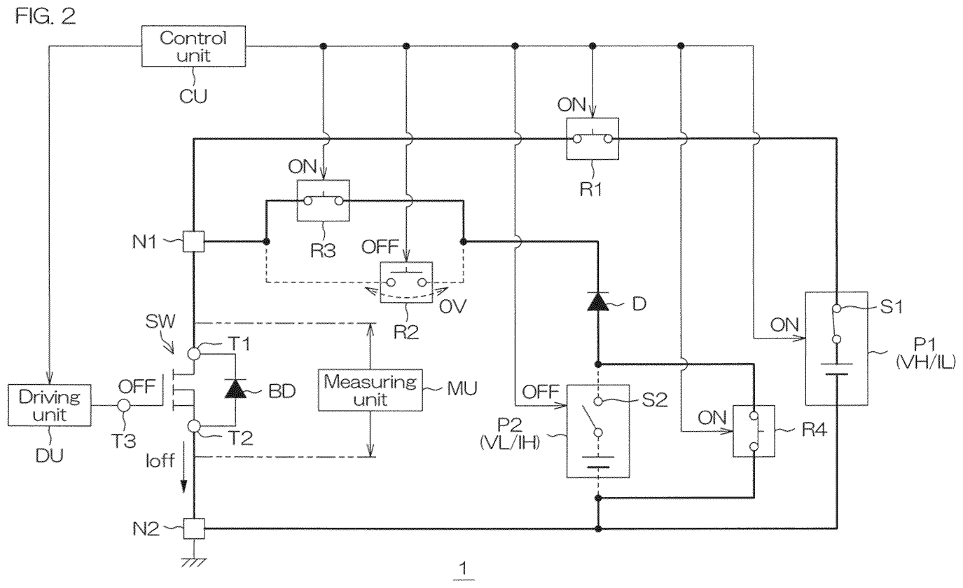

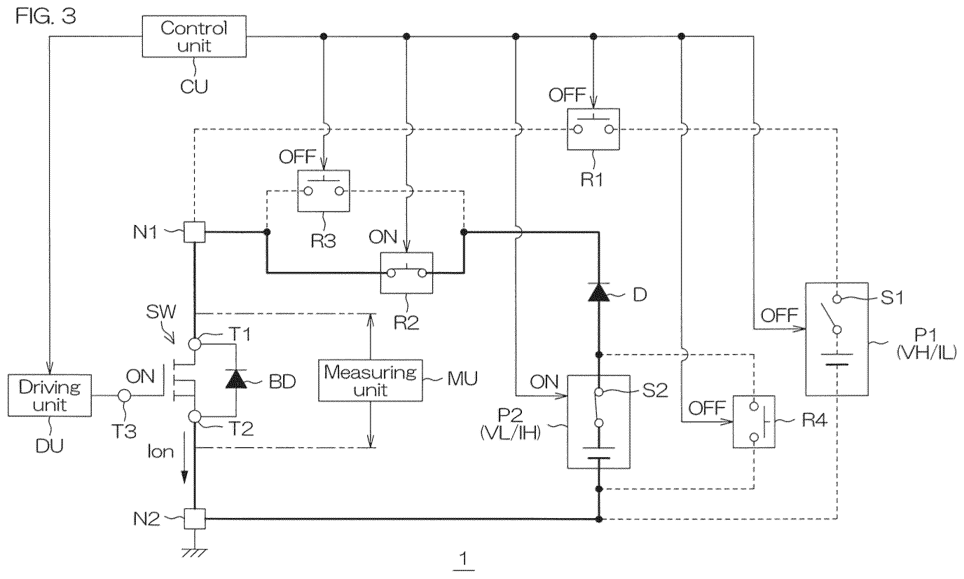

The high-voltage/low-current test and the low-voltage/high-current test for the semiconductor switching device SW shall now be described with reference to FIG. 2 and FIG. 3. FIG. 2 is a circuit diagram showing a circuit operation of the semiconductor test apparatus 1 during the high-voltage/low-current test. FIG. 3 is a circuit diagram showing a circuit operation of the semiconductor test apparatus 1 during the low-voltage/high-current test. In FIG. 2 and FIG. 3, energized locations are indicated by thick lines and non-energized locations are indicated by broken lines for clarity.

The order of the high-voltage/low-current test (see FIG. 2) and the low-voltage/high-current test (see FIG. 3) is arbitrary. Thus, the low-voltage/high-current test (see FIG. 3) may be performed after the high-voltage/low-current test (see FIG. 2) or the high-voltage/low-current test (see FIG. 2) may be performed after the low-voltage/high-current test (see FIG. 3). The high-voltage/low-current test (see FIG. 2) may be performed once or a plurality of times. The low-voltage/high-current test (see FIG. 3) may be performed once or a plurality of times.

Referring to FIG. 2, the high-voltage/low-current test is performed on the semiconductor switching device SW in the off state. When the high-voltage/low-current test is performed, the semiconductor switching device SW is controlled to be in the off state, the first power supply P1 (the first power supply switch S1) is controlled to be in the on state, the second power supply P2 (the second power supply switch S2) is controlled to be in the off state, the first relay R1 is controlled to be in the conducting state, the second relay R2 is controlled to be in the nonconducting third relay R3 is controlled to be in the conducting state, and the fourth relay R4 is controlled to be in the conducting state.

A parallel circuit in which the semiconductor switching device SW and the semiconductor rectifier D are each connected in parallel to the first power supply P1 is thereby arranged. In this parallel circuit, the first voltage VH is applied to the semiconductor switching device SW in the off state and the leak current Ioff directed from the first terminal T1 to the second terminal T2 is generated in the semiconductor switching device SW. The leak current Ioff is measured by the measuring unit MU (ammeter). Here, the leak current Ioff in a voltage range of less than the first breakdown voltage VB1 of the semiconductor switching device SW is measured. The leak current Ioff is less than the first current IL.

The third relay R3, the fourth relay R4, and the semiconductor rectifier D constitute a protective circuit that protects the second relay R2 and the second power supply P2 from the load due to the first power supply P1. The third relay R3 short-circuits the second relay R2 and fixes the voltage across terminals of the second relay R2 at zero voltage. Failure of the second relay R2 due to the first voltage VH is thus suppressed.

On the other hand, whereas the first voltage VH is applied as the load to the third relay R3, the third relay R3 has the third withstand voltage of not less than the first voltage VH. Failure of the third relay R3 due to the first voltage VH is thus suppressed. The fourth relay R4 short-circuits the second power supply P2 that is in the off state and fixes the voltage across terminals of the second power supply P2 at the ground voltage. Failure of the second power supply P2 due to the first voltage VH is thus suppressed.

The semiconductor rectifier D is electrically connected to the first node portion N1 via the third relay R3 and electrically connected to the second node portion N2 via the fourth relay R4. By being electrically interposed between the third relay R3 and the fourth relay R4, the semiconductor rectifier D forms a voltage drop from the first voltage VH to the ground voltage from the third relay R3 toward the fourth relay R4 side. That is, the fourth relay R4 (the voltage across terminals of the second power supply P2) can be regarded as being fixed at zero voltage by the semiconductor rectifier D.

Whereas the first voltage VH is applied as the load to the semiconductor rectifier D, the semiconductor rectifier D has the second breakdown voltage VB2 of not less than the first voltage VH. The semiconductor rectifier D therefore does not fail due to the first voltage VH. Also, the semiconductor rectifier D does not break down due to the first voltage VH and therefore, a current path between the third relay R3 and the fourth relay R4 is interrupted by the semiconductor rectifier D. Failure of the apparatus (for example, failure of the second power supply P2, the third relay R3, the fourth relay R4, etc.) due to breakdown of the semiconductor rectifier D is thereby suppressed.

In this embodiment, whereas the second relay R2 and the fourth relay R4 are of the low-withstand-voltage/high-current type and can each have a comparatively large parasitic capacitance, since a current path between the second relay R2 and the fourth relay R4 is interrupted by the semiconductor rectifier D, degradation of detection precision of the leak current Ioff due to the parasitic capacitance of the second relay R2 and the parasitic capacitance of the fourth relay R4 is suppressed.

Referring to FIG. 3, the low-voltage/high-current test is performed on the semiconductor switching device SW in the on state. When the low-voltage/high-current test is performed, the semiconductor switching device SW is controlled to be in the on state, the first power supply P1 (the first power supply switch S1) is controlled to be in the off state, the second power supply P2 (the second power supply switch S2) is controlled to be in the on state, the first relay R1 is controlled to be in the nonconducting state, the second relay R2 is controlled to be in the conducting state, the third relay R3 is controlled to be in the nonconducting state, and the fourth relay R4 is controlled to be in the nonconducting state.

A series circuit (closed circuit) that includes the second power supply P2, the second relay R2, the semiconductor rectifier D, and the semiconductor switching device SW is thereby formed (see thick lines). This series circuit does not include the first power supply P1, the first relay R1, the third relay R3, and the fourth relay R4 (see broken lines). The second current IH (high current) from the second power supply P2 is applied to the semiconductor switching device SW via the second relay R2 and the semiconductor rectifier D that tolerate the high current.

An on current Ion (drain-source current) directed from the first terminal T1 to the second terminal T2 thereby flows through the semiconductor switching device SW. The on resistance Ron of the semiconductor switching device SW is measured by the measuring unit MU. For example, the on resistance Ron is calculated by division of the voltage between terminals of the semiconductor switching device SW by the on current Ion of the semiconductor switching device SW (Ron=V1/Ion). The first relay R1, the third relay R3, and the fourth relay R4 are in nonconducting states and therefore prevented from failure due to the second current IH.

As described above, the semiconductor test apparatus 1 includes the first node portion N1, the second node portion N2, the first power supply P1 for the high-voltage/low-current test, the second power supply P2 for the low-voltage/high-current test, the first relay R1, the second relay R2, the third relay R3, and the fourth relay R4. The first node portion N1 is arranged such that one end of the semiconductor switching device SW is to be electrically connected thereto. The second node portion N2 is arranged such that the other end of the semiconductor switching device SW is to be electrically connected thereto.

The first power supply P1 is arranged such as to generate the first voltage VH and the first current IL. The second power supply P2 is arranged such as to generate the second voltage VL that is lower than the first voltage VH and the second current IH that is higher than the first current IL. The first relay R1 has the first withstand voltage of not less than the first voltage VH and is electrically interposed between the first node portion N1 and the first power supply P1. The second relay R2 has the second withstand voltage of not less than the second voltage VL and is electrically interposed between the first node portion N1 and the second power supply P2.

The third relay R3 has the third withstand voltage of not less than the first voltage VH and is connected in parallel to the second relay R2. The fourth relay R4 has the fourth withstand voltage of not less than the second voltage VL and is connected in parallel to the second power supply P2. With this arrangement, the semiconductor test apparatus 1 that is capable of performing the high-voltage/low-current test (see FIG. 2) and the low-voltage/high-current test (see FIG. 3) on the semiconductor switching device SW can be provided.

The semiconductor test apparatus 1 preferably includes the semiconductor rectifier D that is electrically interposed between the second power supply P2 and the second relay R2. With this arrangement, the withstand voltage of the semiconductor rectifier D can be used to protect the second power supply P2 from the load due to the first power supply P1.

The semiconductor test apparatus 1 is effective for testing a power semiconductor device that is used under an environment of high load (high voltage and high current). The semiconductor test apparatus 1 is effective for testing semiconductor a wide bandgap switching device. The semiconductor test apparatus 1 is especially effective for testing an SiC semiconductor switching device.

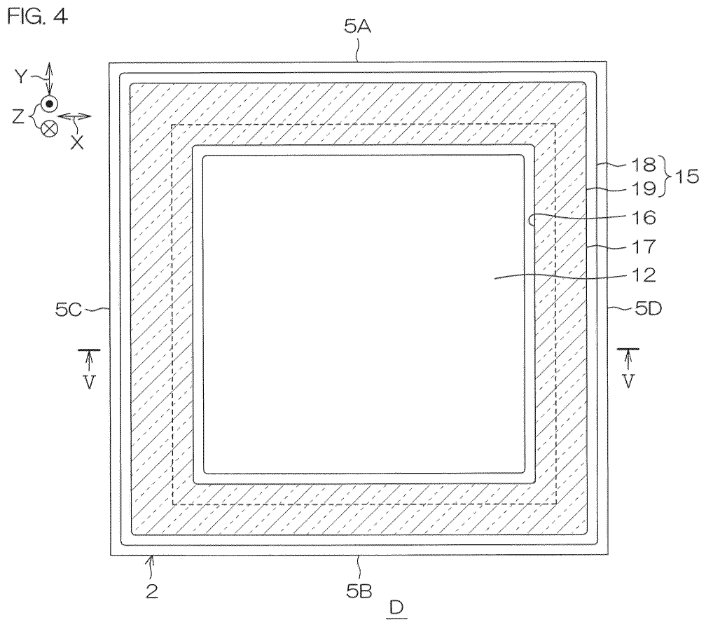

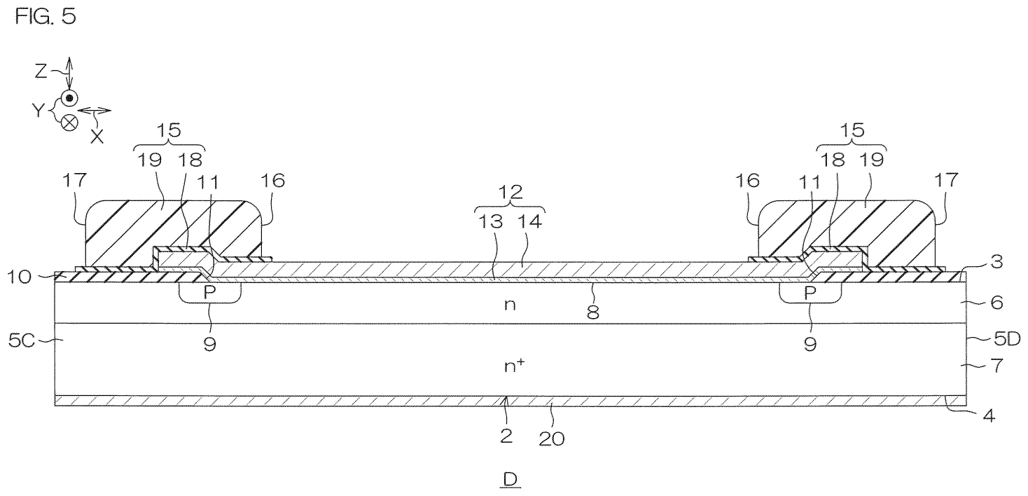

A configuration example of the semiconductor rectifier D shown in FIG. 1 shall now be illustrated. FIG. 4 is a plan view of the semiconductor rectifier D shown in FIG. 1. FIG. 5 is a sectional view taken along line V-V shown in FIG. 4. Referring to FIG. 4 and FIG. 5, the semiconductor rectifier D includes a chip 2 that is formed in a hexahedral shape (specifically, a rectangular parallelepiped shape).

The chip 2 may be an Si chip that includes an SiC monocrystal. That is, the semiconductor rectifier D may be an “Si semiconductor rectifier.” The chip 2 is preferably constituted of a wide bandgap semiconductor chip that includes a monocrystal of a wide bandgap semiconductor. That is, the semiconductor rectifier D is preferably a “wide bandgap semiconductor rectifier.”

In this embodiment, the chip 2 is an SiC chip that includes an SiC monocrystal that is a hexagonal crystal. That is, the semiconductor rectifier D is an “Sic semiconductor rectifier.” The SiC monocrystal that is a hexagonal crystal has a plurality of polytypes including a 2H (hexagonal)-SiC monocrystal, a 4H—SiC monocrystal, a 6H—SiC monocrystal, etc. Although in this embodiment, an example in which the chip 2 includes the 4H—SiC monocrystal is given, selection of another polytype is not excluded.

The chip 2 has a first main surface 3 on one side, a second main surface 4 on another side, and first to fourth side surfaces 5A to 5D connecting the first main surface 3 and the second main surface 4. The first main surface 3 and the second main surface 4 are each formed in a quadrangle shape in a plan view as viewed from a normal direction Z thereto (hereinafter referred to simply as “plan view”). The normal direction Z is also a thickness direction of the chip 2. The first main surface 3 and the second main surface 4 are preferably formed by c-planes of the SiC monocrystal.

In this case, preferably, the first main surface 3 is formed by a silicon surface of the SiC monocrystal and the second main surface 4 is formed by a carbon surface of the SiC monocrystal. The first main surface 3 and the second main surface 4 may each have an off angle inclined in a predetermined off direction at a predetermined angle with respect to the c-plane. The off direction is preferably an a-axis direction ([11-20] direction) of the SiC monocrystal. The off angle may exceed 0° and be not more than 10°. The off angle is preferably not more than 5°.

The first side surface 5A and the second side surface 5B extend in a first direction X that is oriented along the first main surface 3 and are opposed in a second direction Y that intersects (specifically, is orthogonal to) the first direction X. The third side surface 5C and the fourth side surface 5D extend in the second direction Y and are opposed in the first direction X. The first direction X may be an m-axis direction ([1-100] direction) of the SiC monocrystal and the second direction Y may be an a-axis direction of the SiC monocrystal. As a matter of course, the first direction X may instead be the a-axis direction of the SiC monocrystal and the second direction Y may instead be the m-axis direction of the SiC monocrystal.

The semiconductor rectifier D includes a first semiconductor region 6 of an n-type that is formed in a region (surface layer portion) inside the chip 2 at the first main surface 3 side. The first semiconductor region 6 is formed in a layered shape extending along the first main surface 3 and is exposed from the first main surface 3 and the first to fourth side surfaces 5A to 5D. In this embodiment, the first semiconductor region 6 is constituted of an epitaxial layer (SiC epitaxial layer).

The semiconductor rectifier D includes a second semiconductor region 7 of the n-type that is formed in a region (surface layer portion) inside the chip 2 at the second main surface 4 side. The second semiconductor region 7 has an n-type impurity concentration higher than that of the first semiconductor region 6 and is electrically connected to the first semiconductor region 6 inside the chip 2. The second semiconductor region 7 is formed in a layered shape extending along the second main surface 4 and is exposed from the second main surface 4 and the first to fourth side surfaces 5A to 5D.

In this embodiment, the second semiconductor region 7 is constituted of a semiconductor substrate (SiC substrate). That is, the chip 2 has a laminated structure that includes the substrate and the epitaxial layer. A thickness of the second semiconductor region 7 may be greater than a thickness of the first semiconductor region 6. The thickness of the second semiconductor region 7 may be less than the thickness of the first semiconductor region 6. As a matter of course, a mode not having the second semiconductor region 7 (semiconductor substrate) may also be adopted. That is, the chip 2 may have a single layer structure constituted of the epitaxial layer.

The semiconductor rectifier D includes a diode region 8 of the n-type that is formed in a surface layer portion of the first main surface 3. In this embodiment, the diode region 8 is formed using the first semiconductor region 6. The diode region 8 is formed in an inner portion of the first main surface 3 at an interval from a peripheral edge (first to fourth side surfaces 5A to 5D) of the first main surface 3. The diode region 8 is formed in a polygonal shape (in this embodiment, a quadrangle shape) in plan view.

The semiconductor rectifier D includes a guard region 9 of a p-type (second conductivity type) that is formed in a surface layer portion of the first main surface 3. The guard region 9 is formed in a surface layer portion of the first semiconductor region 6 at an interval inward from the peripheral edge of the first main surface 3. The guard region 9 is formed in a polygonal annular shape (in this embodiment, a quadrangle annular shape) that surrounds the diode region 8 in plan view. The guard region 9 has an inner edge portion at an inner side of the first main surface 3 and an outer edge portion at a peripheral edge side of the first main surface 3.

The semiconductor rectifier D includes a main surface insulating film 10 that selectively covers the first main surface 3. The main surface insulating film 10 may include at least one among a silicon oxide film, a silicon nitride film, and a silicon oxynitride film. In this embodiment, the main surface insulating film 10 has a single layer structure that includes a silicon oxide film. The main surface insulating film 10 especially preferably includes a silicon oxide film constituted of an oxide of the chip 2.

The main surface insulating film 10 has a contact opening 11 that exposes the diode region 8 and the inner edge portion of the guard region 9. The contact opening 11 may be formed in a polygonal shape (in this embodiment, a quadrangle shape) that extends along a peripheral edge of the diode region 8 (the inner edge portion of the guard region 9) in plan view. The main surface insulating film 10 covers the first main surface 3 such as to be continuous to the peripheral edge of the first main surface 3. As a matter of course, the main surface insulating film 10 may instead cover the first main surface 3 at an interval inward from the peripheral edge of the first main surface 3 such as to expose a peripheral edge portion of the first main surface 3.

The semiconductor rectifier D includes a first polarity terminal 12 that forms a Schottky junction with the diode region 8. The first polarity terminal 12 is formed as an anode terminal (the anode of the semiconductor rectifier D). The first polarity terminal 12 enters into the contact opening 11 from above the main surface insulating film 10 and is electrically connected to the diode region 8 and the inner edge portion of the guard region 9. The first polarity terminal 12 is arranged at an interval inward from the peripheral edge of the first main surface 3 and is formed in a polygonal shape (in this embodiment, a quadrangle shape) oriented along the peripheral edge of the first main surface 3 in plan view.

The first polarity terminal 12 has a laminated structure including a first electrode film 13 and a second electrode film 14 that are laminated in that order from the first main surface 3 side. The first electrode film 13 is a Schottky barrier electrode film that forms a Schottky junction with the diode region 8. As long as the Schottky barrier is formed, the material of the first electrode film 13 is arbitrary.

The first electrode film 13 may be constituted of a metal film containing at least one type among magnesium (Mg), aluminum (Al), titanium (Ti), vanadium (V), chromium (Cr), manganese (Mn), cobalt (Co), nickel (Ni), copper (Cu), zirconium (Zr), niobium (Nb), molybdenum (Mo), palladium (Pd), silver (Ag), indium (In), tin (Sn), tantalum (Ta), tungsten (W), platinum (Pt), and gold (Au). As a matter of course, the first electrode film 13 may be constituted of an alloy film containing at least one type among the above metal species. In this embodiment, the first electrode film 13 is constituted of a Ti film.

The second electrode film 14 is constituted of a Cu-based metal film or an Al-based metal film and has a thickness greater than a thickness of the first electrode film 13. The second electrode film 14 may include at least one type among a pure Cu film (a Cu film with a purity of not less than 99%), a pure Al film (an Al film with a purity of not less than 99%), an AlCu alloy film, an AlSi alloy film, and an AlSiCu alloy film. In this embodiment, the second electrode film 14 has a single layer structure constituted of an AlCu alloy film.

The semiconductor rectifier D includes an upper insulating film 15 that covers the first polarity terminal 12. The upper insulating film 15 is preferably thicker than the first polarity terminal 12. A thickness of the upper insulating film 15 is preferably less than a thickness of the chip 2. The upper insulating film 15 is formed at an interval inward from the peripheral edge of the first main surface 3 and covers a peripheral edge portion of the first polarity terminal 12. The upper insulating film 15 demarcates a pad opening 16 at an inner portion side of the chip 2 and demarcates a street region 17 at a peripheral edge portion side of the chip 2.

The pad opening 16 exposes an inner portion of the first polarity terminal 12. The pad opening 16 is formed in a polygonal shape (in this embodiment, a quadrangle shape) oriented along a peripheral edge of the first polarity terminal 12 in plan view. The street region 17 extends along a peripheral edge of the chip 2 and exposes the main surface insulating film 10. As a matter of course, when the main surface insulating film 10 exposes the peripheral edge portion of the first main surface 3, the street region 17 may expose the peripheral edge portion of the first main surface 3.

In this embodiment, the upper insulating film 15 has a laminated structure that includes an inorganic insulating film 18 (inorganic film) and an organic insulating film 19 (organic film) that are laminated in that order from the first polarity terminal 12 side. The inorganic insulating film 18 may include at least one among a silicon oxide film, a silicon nitride film, and a silicon oxynitride film. The inorganic insulating film 18 preferably includes an insulating material differing from the main surface insulating film 10. In this embodiment, the inorganic insulating film 18 has a single layer structure that includes a silicon nitride film. The inorganic insulating film 18 preferably has a smaller thickness than a thickness of the first polarity terminal 12.

The organic insulating film 19 is thicker than the inorganic insulating film 18 and covers the inorganic insulating film 18. The organic insulating film 19 preferably has a thickness greater than the thickness of the first polarity terminal 12. The organic insulating film 19 is preferably constituted of a photosensitive resin film. The organic insulating film 19 may include at least one among a polyimide film, a polyamide and a film, polybenzoxazole film.

The organic insulating film 19 may expose an inner edge portion of the inorganic insulating film 18 inside the pad opening 16. The organic insulating film 19 may expose an outer edge portion of the inorganic insulating film 18 inside the street region 17. The organic insulating film 19 may expose one of either or both of the inner edge portion and the outer edge portion of the inorganic insulating film 18.

In this embodiment, the organic insulating film 19 exposes both the inner edge portion and the outer edge portion of the inorganic insulating film 18 and, together with the inorganic insulating film 18, demarcates the pad opening 16 and the street region 17. As a matter of course, the organic insulating film 19 may cover both the inner edge portion and the outer edge portion of the inorganic insulating film 18 instead.

The semiconductor rectifier D includes a second polarity terminal 20 that covers the second main surface 4. The second polarity terminal 20 is formed as a cathode terminal (the cathode of the semiconductor rectifier D). The second polarity terminal 20 is electrically connected to the second semiconductor region 7 exposed from the second main surface 4. The second polarity terminal 20 may include at least one among an Al-based metal film, a Ti-based metal film, an Ni-based metal film, a Pd-based metal film, an Au-based metal film, and an Ag-based metal film.

For example, the second polarity terminal 20 may have a laminated structure that includes a Ti film, an Ni film, and an Au film that are laminated in that order from the second main surface 4 side. For example, the second polarity terminal 20 may have a laminated structure that includes an AlSi alloy film, a Ti film, an Ni film, and an Au film that are laminated in that order from the second main surface 4 side. For example, the second polarity terminal 20 may have a laminated structure that includes a Ti film, an Ni film, an Au film and an Ag film that are laminated in that order from the second main surface 4 side.

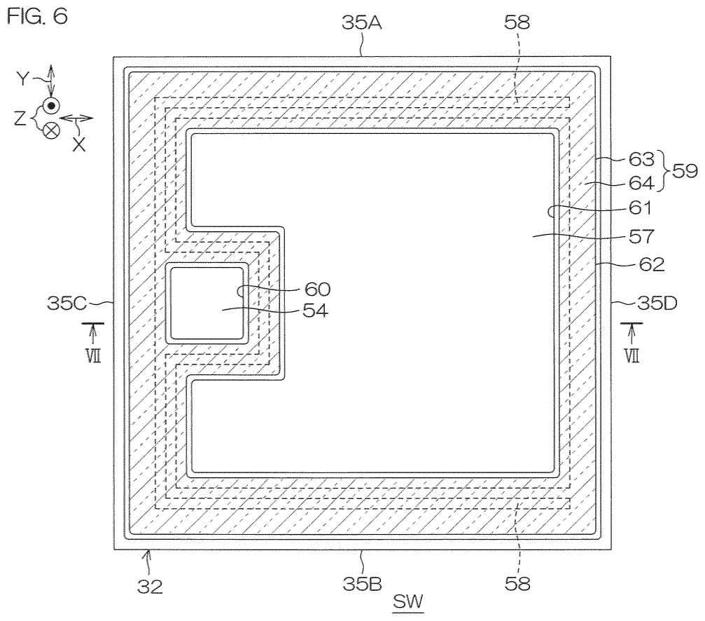

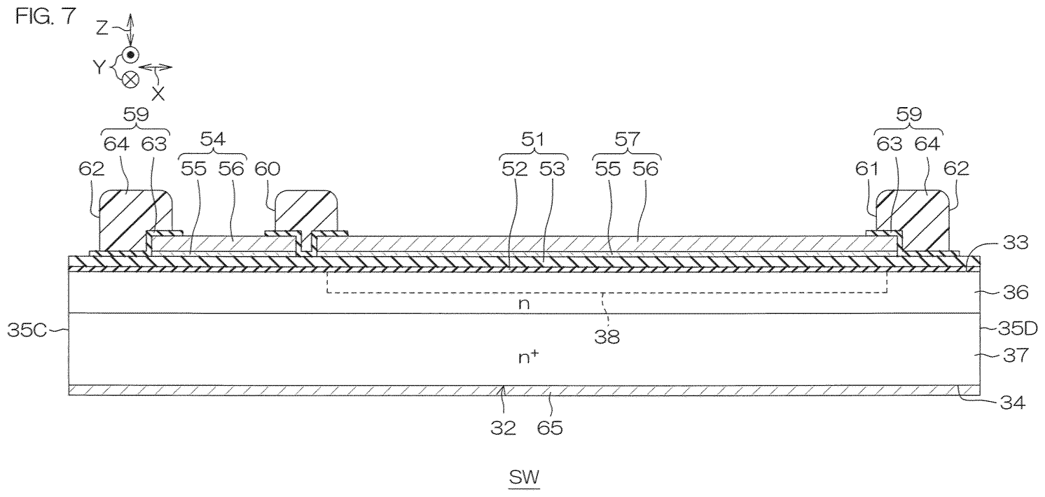

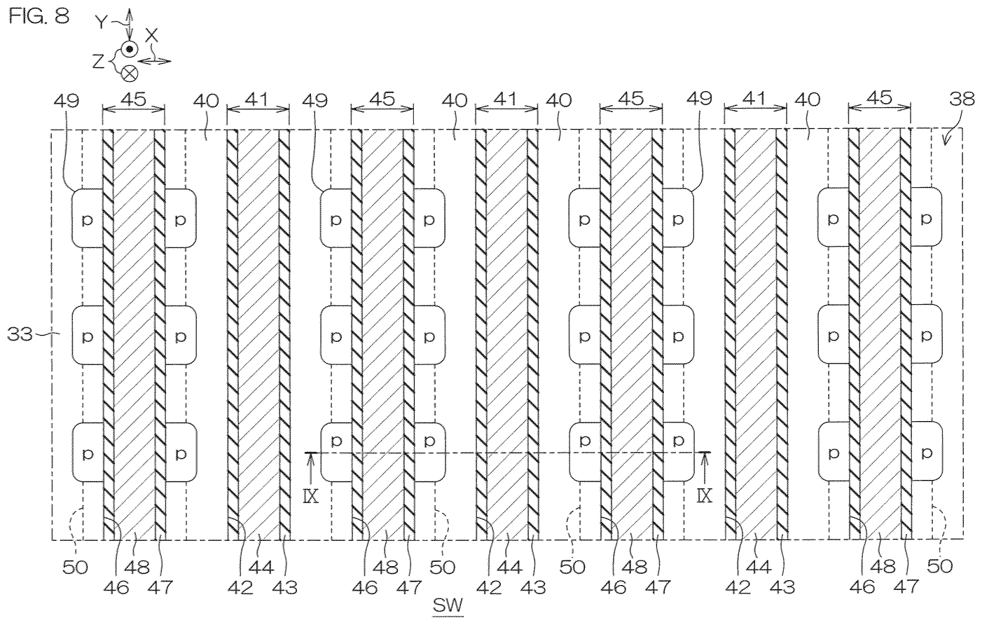

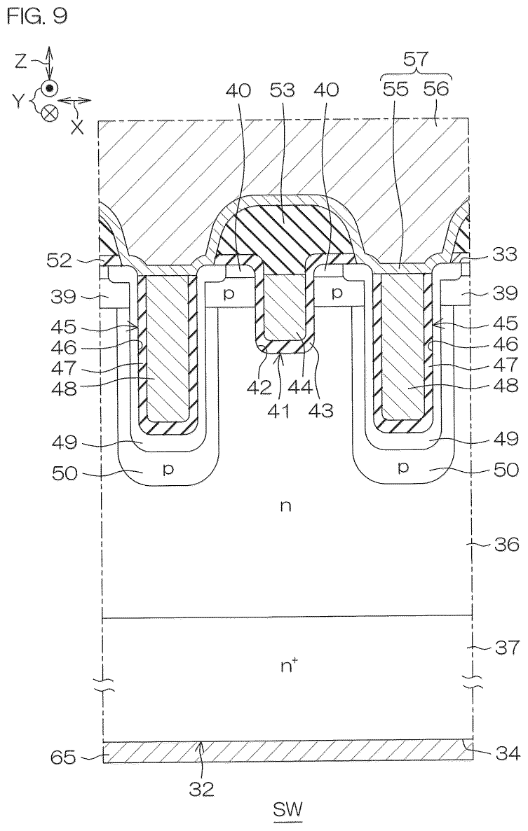

A configuration example of the semiconductor switching device SW shown in FIG. 1 shall now be illustrated. FIG. 6 is a plan view showing an example of the semiconductor switching device SW (the tested device). FIG. 7 is a sectional view taken along line VII-VII shown in FIG. 6. FIG. 8 is a plan view showing an internal arrangement (a transistor structure 38) of the semiconductor switching device SW shown in FIG. 6. FIG. 9 is a sectional view taken along line IX-IX shown in FIG. 8.

Referring to FIG. 6 to FIG. 9, the semiconductor switching device SW includes a chip 32 that is formed in a hexahedral shape (specifically, a rectangular parallelepiped shape). The chip 32 may be an Si chip that includes an Si monocrystal. That is, the semiconductor switching device SW may be an “Si semiconductor switching device.” The chip 32 is preferably constituted of a wide bandgap semiconductor chip that includes a monocrystal of a wide bandgap semiconductor. That is, the semiconductor switching device SW is preferably a “wide bandgap semiconductor switching device.”

In this embodiment, the chip 32 is an SiC chip that includes an SiC monocrystal that is a hexagonal crystal. That is, the semiconductor switching device SW is an “SiC semiconductor switching device.” The SiC monocrystal that is a hexagonal crystal has a plurality of polytypes including a 2H (hexagonal)-SiC monocrystal, a 4H-SiC monocrystal, a 6H-SiC monocrystal, etc. Although in this embodiment, an example in which the chip 32 includes the 4H-SiC monocrystal is given, selection of another polytype is not excluded.

The chip 32 has a first main surface 33 on one side, a second main surface 34 on another side, and first to fourth side surfaces 35A to 35D connecting the first main surface 33 and the second main surface 34. The first main surface 33 and the second main surface 34 are each formed in a quadrangle shape in a plan view as viewed from the normal direction Z thereto (hereinafter referred to simply as “plan view”). The normal direction Z is also a thickness direction of the chip 32. The first main surface 33 and the second main surface 34 are preferably formed by c-planes of the SiC monocrystal.

In this case, preferably, the first main surface 33 is formed by a silicon surface of the SiC monocrystal and the second main surface 34 is formed by a carbon surface of the SiC monocrystal. The first main surface 33 and the second main surface 34 may each have an off angle inclined in a predetermined off direction at a predetermined angle with respect to the c-plane. The off direction is preferably an a-axis direction ([11-20] direction) of the SiC monocrystal. The off angle may exceed 0° and be not more than 10°. The off angle is preferably not more than 5°.

The first side surface 35A and the second side surface 35B extend in the first direction X that is oriented along the first main surface 33 and are opposed in the second direction Y that intersects (specifically, is orthogonal to) the first direction X. The third side surface 35C and the fourth side surface 35D extend in the second direction Y and are opposed in the first direction X. The first direction X may be an m-axis direction ([1-100]direction) of the SiC monocrystal and the second direction Y may be an a-axis direction of the Sic monocrystal. As a matter of course, the first direction X may instead be the a-axis direction of the SiC monocrystal and the second direction Y may instead be the m-axis direction of the SiC monocrystal.

The semiconductor switching device SW includes a first semiconductor region 36 of the n-type that is formed in a region (surface layer portion) inside the chip 32 at the first main surface 33 side. The first semiconductor region 36 is electrically connected to the first node portion N1 described above. The first semiconductor region 36 is formed in a layered shape extending along the first main surface 33 and is exposed from the first main surface 33 and the first to fourth side surfaces 35A to 35D. In this embodiment, the first semiconductor region 36 is constituted of an epitaxial layer (SiC epitaxial layer).

The semiconductor switching device SW includes a second semiconductor region 37 of the n-type that is formed in a region (surface layer portion) inside the chip 32 at the second main surface 34 side. The second semiconductor region 37 has an n-type impurity concentration higher than that of the first semiconductor region 36 and is electrically connected to the first semiconductor region 36 inside the chip 32. The second semiconductor region 37 is formed in a layered shape extending along the second main surface 34 and is exposed from the second main surface 34 and the first to fourth side surfaces 35A to 35D.

In this embodiment, the second semiconductor region 37 is constituted of a semiconductor substrate (SiC substrate). That is, the chip 32 has a laminated structure that includes the substrate and the epitaxial layer. A thickness of the second semiconductor region 37 may be greater than a thickness of the first semiconductor region 36. The thickness of the second semiconductor region 37 may be less than the thickness of the first semiconductor region 36. As a matter of course, a mode not having the second semiconductor region 37 (semiconductor substrate) may also be adopted. That is, the chip 32 may have a single layer structure constituted of the epitaxial layer.

The semiconductor switching device SW includes the transistor structure 38 that is formed in the first main surface 33. In this embodiment, the transistor structure 38 is of a trench gate type. The transistor structure 38 shall be described specifically below.

The semiconductor switching device SW includes a body region 39 of the p-type that is formed in a surface layer portion of the first main surface 33. The body region 39 forms a pn junction portion as the body diode BD with the first semiconductor region 36 and is to be electrically connected to the second node portion N2 described above. The body region 39 may also be referred to as a “base region” or a “channel region.” The body region 39 is formed at an interval to the first main surface 33 side from a bottom portion of the first semiconductor region 36 and extends in a layered shape in the surface layer portion of the first main surface 33. The body region 39 may be formed in an inner portion of the first main surface 33 at an interval from the peripheral edge of the first main surface 33.

The semiconductor switching device SW includes a source region 40 of the n-type that is formed in a surface layer portion of the body region 39. The source region 40 is to be electrically connected to the second node portion N2 described above. The source region 40 may be formed in the inner portion of the first main surface 33 at an interval from the peripheral edge of the first main surface 33.

The source region 40 has a higher n-type impurity concentration than the first semiconductor region 36. The source region 40 is formed at an interval to the first main surface 33 side from a bottom portion of the body region 39 and extends in a layered shape in the surface layer portion Inside the body region 39, of the first main surface 33, the source region 40 forms channels with the first semiconductor region 36.

The semiconductor switching device SW includes a plurality of first trench structures 41 that are formed in the first main surface 33. The first trench structures 41 are to be electrically connected to the driving unit DU described above and the control signals from the driving unit DU are to be applied thereto. The first trench structures 41 control inversion and non-inversion of the channels. The first trench structures 41 may referred to as “trench gate structures.”

The first trench structures 41 penetrate through the body region 39 and the source region 40 and reach the first semiconductor region 36. In plan view, the plurality of first trench structures 41 may be arranged at intervals in the first direction X and may each be formed in a band shape extending in the second direction Y. The plurality of first trench structures 41 are formed at an interval to the first main surface 33 side from a bottom portion of the first semiconductor region 36.

Each first trench structure 41 includes a first trench 42, a first insulating film 43, and a first embedded electrode 44. The first trench 42 is formed in the first main surface 33 and demarcates a wall surface of the first trench 42. The first insulating film 43 may include at least one among a silicon oxide film, a silicon nitride film, and a silicon oxynitride film. In this embodiment, the first insulating film 43 has a single layer structure that includes a silicon oxide film. The first insulating film 43 especially preferably includes a silicon oxide film constituted of an oxide of the chip 32.

The first insulating film 43 covers the wall surface of the first trench 42. The first embedded electrode 44 may contain a conductive polysilicon. The first embedded electrode 44 is embedded in the first trench 42 with the first insulating film 43 interposed therebetween. The first embedded electrode 44 opposes a channel with the first insulating film 43 interposed therebetween.

The semiconductor switching device SW includes a plurality of second trench structures 45 that are formed in the first main surface 33. The plurality of second trench structures 45 are to be electrically connected to the second node portion N2 described above. The second trench structures 45 may be referred to as “trench source structures.” The plurality of second trench structures 45 are each formed in a region between two adjacent first trench structures 41.

The plurality of second trench structures 45 may each be formed in a band shape extending in the second direction Y in plan view. The second trench structures 45 penetrate through the body region 39 and the source region 40 and reach the first semiconductor region 36. The plurality of second trench structures 45 are formed at an interval to the first main surface 33 side from the bottom portion of the first semiconductor region 36.

In this embodiment, the plurality of second trench structures 45 are formed deeper than the plurality of first trench structures 41. A depth of the second trench structures 45 may be not less than 1.5 times and not more than 4 times (preferably not more than 2.5 times) a depth of the first trench structures 41. As a matter of course, the depth of the second trench structures 45 may be substantially equal to the depth of the first trench structures 41.

Each second trench structure 45 includes a second trench 46, a second insulating film 47, and a second embedded electrode 48. The second trench 46 is formed in the first main surface 33 and demarcates a wall surface of the second trench 46. The second insulating film 47 may include at least one among a silicon oxide film, a silicon nitride film, and a silicon oxynitride film.

In this embodiment, the second insulating film 47 has a single layer structure that includes a silicon oxide film. The second insulating film 47 especially preferably includes the silicon oxide film constituted of the oxide of the chip 32. The second insulating film 47 covers the wall surface of the second trench 46. The second embedded electrode 48 may contain a conductive polysilicon. The second embedded electrode 48 is embedded in the second trench 46 with the second insulating film 47 interposed therebetween.

The semiconductor switching device SW includes a plurality of contact regions 49 of the p-type that are respectively formed in regions inside the chip 32 along the plurality of second trench structures 45. Each contact region 49 has a higher p-type impurity concentration than the body region 39. Each contact region 49 covers a side wall and a bottom wall of the corresponding second trench structure 45 and is electrically connected to the body region 39 in the surface layer portion of the first main surface 33.

The semiconductor switching device SW includes a plurality of well regions 50 of the p-type that are respectively formed in regions inside the chip 32 along the plurality of second trench structures 45. Each well region 50 has a p-type impurity concentration that is higher than that of the body region 39 and lower than that of the contact regions 49. Each well region 50 covers the corresponding second trench structure 45 with the corresponding contract region 49 interposed therebetween. Each well region 50 covers the side wall and the bottom wall of the corresponding second trench structure 45 and is electrically connected to the body region 39 in the surface layer portion of the first main surface 33.

The semiconductor switching device SW includes a main surface insulating film 51 that selectively covers the first main surface 33. In this embodiment, the main surface insulating film 51 includes a first main surface insulating film 52 and a second main surface insulating film 53. The first main surface insulating film 52 may include at least one among a silicon oxide film, a silicon nitride film, and a silicon oxynitride film. In this embodiment, the first main surface insulating film 52 has a single layer structure that includes a silicon oxide film. The first main surface insulating film 52 especially preferably includes the silicon oxide film constituted of the oxide of the chip 32.

The first main surface insulating film 52 is continuous to the first insulating film 43 and the second insulating film 47 and exposes the first embedded electrode 44 and the second embedded electrode 48. In this embodiment, the first main surface insulating film 52 covers a peripheral edge portion of the first main surface 33 such as to be continuous to the peripheral edge of the first main surface 33. As a matter of course, the main surface insulating film 51 may instead expose the peripheral edge portion of the first main surface 33.

The second main surface insulating film 53 may include at least one among a silicon oxide film, a silicon nitride film, and a silicon oxynitride film. In this embodiment, the second main surface insulating film 53 includes a silicon oxide film. The second main surface insulating film 53 has a thickness greater than a thickness of the first main surface insulating film 52 and covers the first main surface insulating film 52. The second main surface insulating film 53 covers the plurality of first trench structures 41 and the plurality of second trench structures 45.

In this embodiment, the second main surface insulating film 53 covers the peripheral edge portion of the first main surface 33 such as to be continuous to the peripheral edge of the first main surface 33 with the first main surface insulating film 52 interposed therebetween. As a matter of course, when the first main surface insulating film 52 exposes the peripheral edge portion of main surface 33, the second main surface the first insulating film 53 may expose the peripheral edge portion of the first main surface 33.

The semiconductor switching device SW includes a gate terminal 54 that is arranged on the main surface insulating film 51. The gate terminal 54 is formed as the control terminal T3 of the semiconductor switching device SW. The gate terminal 54 has a laminated structure including a first electrode film 55 and a second electrode film 56 that are laminated in that order from the first main surface 33 (main surface insulating film 51) side. The first electrode film 55 includes a Ti-based metal film. The first electrode film 55 may have a single layer structure or a laminated structure that includes at least one among a Ti film and a TiN film.

The second electrode film 56 is constituted of a Cu-based metal film or an Al-based metal film and has a thickness greater than a thickness of the first electrode film 55. The second electrode film 56 may include at least one type among a pure Cu film (a Cu film with a purity of not less than 99%), a pure Al film (an Al film with a purity of not less than 99%), an AlCu alloy film, an AlSi alloy film, and an AlSiCu alloy film. In this embodiment, the second electrode film 56 has a single layer structure constituted of an AlCu alloy film.

In this embodiment, the gate terminal 54 is arranged in a region near a central portion of one side (in this embodiment, the third side surface 35C side) of the first main surface 33 in plan view. An arrangement location of the gate terminal 54 is arbitrary. The gate terminal 54 may be arranged in a corner portion of the first main surface 33 in plan view. The gate terminal 54 may be arranged in a central portion of the first main surface 33 in plan view. In this embodiment, the gate terminal 54 is formed in a polygonal shape (in this embodiment, a quadrangle shape) in plan view.

The semiconductor switching device SW includes a source terminal 57 that is arranged on the main surface insulating film 51 at an interval from the gate terminal 54. The source terminal 57 is formed as the second terminal T2 of the semiconductor switching device SW. As with the gate terminal 54, the source terminal 57 has the laminated structure including the first electrode film 55 and the second electrode film 56 that are laminated in that order from the first main surface 33 (main surface insulating film 51) side.

In this embodiment, the source terminal 57 is formed in a polygonal shape having a recess portion that is recessed along the gate terminal 54 in plan view. As a matter of course, the source terminal 57 may be formed in a quadrangle shape in plan view. When the gate terminal 54 is arranged in the central portion of the first main surface 33, the source terminal 57 may surround the gate terminal 54 in plan view. The source terminal 57 penetrates through the main surface insulating film 51 and is electrically connected to the body region 39, the source region 40, and the plurality of second trench structures 45.

The semiconductor switching device SW includes a gate wiring 58 that is drawn out onto the main surface insulating film 51 from the gate terminal 54. As with the gate terminal 54, the gate wiring 58 has the laminated structure including the first electrode film 55 and the second electrode film 56 that are laminated in that order from the first main surface 33 (main surface insulating film 51) side.

The gate wiring 58 extends along the first to fourth side surfaces 35A to 35D such as to surround the source terminal 57 (the inner portion of the first main surface 33) from multiple directions in plan view. The gate wiring 58 is formed in a band shape that extends along the peripheral edge of the first main surface 33 such as to intersect (specifically, to be orthogonal to) end portions of the plurality of first trench structures 41 in plan view. The gate wiring 58 penetrates through the main surface insulating film 51 and is electrically connected to the plurality of first trench structures 41.

The semiconductor switching device SW includes an upper insulating film 59 that selectively covers the gate terminal 54, the source terminal 57, and the gate wiring 58. The upper insulating film 59 is preferably thicker than the gate terminal 54 and the source terminal 57. A thickness of the upper insulating film 59 is preferably less than a thickness of the chip 32. The upper insulating film 59 is formed at an interval inward from the peripheral edge of the first main surface 33 and covers a peripheral edge portion of the gate terminal 54, a peripheral edge portion of the source terminal 57, and a whole region of the gate wiring 58.

The upper insulating film 59 includes a gate pad opening 60 that exposes an inner portion of the gate terminal 54 and a source pad opening 61 that exposes an inner portion of the source terminal 57. In this embodiment, the gate pad opening 60 is demarcated in a polygonal shape (in this embodiment, a quadrangle shape) oriented along a peripheral edge of the gate terminal 54 in plan view. In this embodiment, the source pad opening 61 is demarcated in a polygonal shape oriented along a peripheral edge of the source terminal 57 in plan view.

The upper insulating film 59 demarcates a street region 62 at a peripheral edge portion side of the chip 32. The street region 62 extends along the peripheral edge of the first main surface 33 and exposes the main surface insulating film 51. As a matter of course, when the main surface insulating film 51 exposes the peripheral edge portion of the first main surface 33, the street region 62 may expose the peripheral edge portion of the first main surface 33.

In this embodiment, the upper insulating film 59 has a laminated structure including an inorganic insulating film 63 (inorganic film) and an organic insulating film 64 (organic film) that are laminated in that order from the first main surface 33 side. The inorganic insulating film 63 may include at least one among a silicon oxide film, a silicon nitride film, and a silicon oxynitride film. The inorganic insulating film 63 preferably includes an insulating material differing from the main surface insulating film 51. In this embodiment, the inorganic insulating film 63 has a single layer structure that includes a silicon nitride film. The inorganic insulating film 63 preferably has a smaller thickness than a thickness of the gate terminal 54 (the source terminal 57).

The organic insulating film 64 is thicker than the inorganic insulating film 63 and covers the inorganic insulating film 63. The organic insulating film 64 preferably has a thickness greater than the thickness of the gate terminal 54 (the source terminal 57). The organic insulating film 64 is preferably constituted a of photosensitive resin film. The organic insulating film 64 may include at least one among a polyimide film, a polyamide film, and a polybenzoxazole film.

The organic insulating film 64 may expose an edge portion (a gate side edge portion) of the inorganic insulating film 63 inside the gate pad opening 60. The organic insulating film 64 may expose an edge portion (a source side edge portion) of the inorganic insulating film 63 inside the source pad opening 61. The organic insulating film 64 may expose an edge portion (a street side edge portion) of the inorganic insulating film 63 in the street region 62. As a matter of course, the organic insulating film 64 may expose a whole region of the inorganic insulating film 63.

The organic insulating film 64 may expose at least one or all of the gate side edge portion, the source side edge portion, and the street side edge portion. In this embodiment, the organic insulating film 64 exposes all of the gate side edge portion, the source side edge portion, and the street side edge portion and, together with the inorganic insulating film 63, demarcates the gate pad opening 60, the source pad opening 61, and the street region 62. As a matter of course, the organic insulating film 64 may cover all of the gate side edge portion, the source side edge portion, and the street side edge portion instead.

The semiconductor switching device SW includes a drain terminal 65 that covers the second main surface 34. The drain terminal 65 is formed as the first terminal T1 of the semiconductor switching device SW. The drain terminal 65 is formed as a drain electrode and is electrically connected to the second semiconductor region 37 exposed from the second main surface 34. The drain terminal 65 may include at least one among an Al-based metal film, a Ti-based metal film, an Ni-based metal film, a Pd-based metal film, an Au-based metal film, and an Ag-based metal film.

For example, the drain terminal 65 may have a laminated structure that includes a Ti film, an Ni film, and an Au film that are laminated in that order from the second main surface 34 side. For example, the drain terminal 65 may have a laminated structure that includes an AlSi alloy film, a Ti film, an Ni film, and an Au film that are laminated in that order from the second main surface 34 side. For example, the drain terminal 65 may have a laminated structure that includes a Ti film, an Ni film, an Au film and an Ag film that are laminated in that order from the second main surface 34 side.

Although the embodiment has been described above, the embodiment can be implemented in yet other modes. For example, although a single semiconductor test apparatus 1 was illustrated with the embodiment described above, a semiconductor test module that includes a plurality of the semiconductor test apparatuses 1 may be adopted. By this module, the high-voltage/low-current test and the low-voltage/high-current test can be performed on a plurality of the semiconductor switching devices SW at the same time.

In regard to the semiconductor switching device SW (see FIG. 6 to FIG. 9) described above, the second semiconductor region 37 of the p-type may be adopted in place of the second semiconductor region 37 of the n-type. In this case, the semiconductor switching device SW includes an IGBT (insulated gate bipolar transistor) instead of the MISFET. A specific configuration in this case is obtained by replacing the “source” of the MISFET with an “emitter” of the IGBT and replacing the “drain” of the MISFET with a “collector” of the IGBT.

With the embodiment described above, a configuration in which a first conductivity type is the n-type and the second conductivity type is the p-type was described. However, in each embodiment described above, a configuration in which the first conductivity type is the p-type and the second conductivity type is the n-type may be adopted. A specific configuration in this case is obtained by replacing the n-type regions with p-type regions and replacing the p-type regions with n-type regions in the above descriptions and attached drawings.

Hereinafter, examples of features extracted from this description and the attached drawings shall be indicated. Hereinafter, the alphanumeric characters, etc., in parentheses represent the corresponding components, etc., in the embodiment described above, but are not intended to limit the scope of each clause to the embodiment. The “semiconductor test apparatus” in the following clauses may be replaced with a “characteristic test apparatus” or a “semiconductor inspection apparatus” as needed.

[A1] A semiconductor test apparatus (1) comprising: a first node portion (N1) to which one end (T1) of a semiconductor switching device (SW) is to be electrically connected; a second node portion (N2) to which another end (T2) of the semiconductor switching device (SW) is to be electrically connected; a first power supply (P1) for high voltage and low current that generates a first voltage (VH) and a first current (IL); a second power supply (P2) for low voltage and high current that generates a second voltage (VL) lower than the first voltage (VH) and a second current (IH) higher than the first current (IL); a first relay (R1) that has a withstand voltage of not less than the first voltage (VH) and is electrically interposed between the first node portion (N1) and the first power supply (P1); a second relay (R2) that has a withstand voltage of not less than the second voltage (VL) and is electrically interposed between the first node portion (N1) and the second power supply (P2); a third relay (R3) that has a withstand voltage of not less than the first voltage (VH) and is connected in parallel to the second relay (R2); and a fourth relay (R4) that has a withstand voltage of not less than the second voltage (VL) and is connected in parallel to the second power supply (P2).

[A2] The semiconductor test apparatus (1) according to A1, wherein when a high-voltage/low-current test is performed on the semiconductor switching device (SW), the first power supply (P1) is controlled to be in an on state, the second power supply (P2) is controlled to be in an off state, the first relay (R1) is controlled to be in a conducting state, the second relay (R2) is controlled to be in a nonconducting state, the third relay (R3) is controlled to be in a conducting state, and the fourth relay (R4) is controlled to be in a conducting state.

[A3] The semiconductor test apparatus (1) according to A1 or A2, wherein when a low-voltage/high-current test is performed on the semiconductor switching device (SW), the first power supply (P1) is controlled to be in an off state, the second power supply (P2) is controlled to be in an on state, the first relay (R1) is controlled to be in a nonconducting state, the second relay (R2) is controlled to be in a conducting state, the third relay (R3) is controlled to be in a nonconducting state, and the fourth relay (R4) is controlled to be in a nonconducting state.

[A4] The semiconductor test apparatus (1) according to any one of A1 to A3, wherein the first voltage (VH) is lower than a breakdown voltage (VB1) of the semiconductor switching device (SW).

[A5] The semiconductor test apparatus (1) according to any one of A1 to A4, wherein the first voltage (VH) is not less than 500 V.

[A6] The semiconductor test apparatus (1) according to any one of A1 to A5, wherein the first current (IL) is not more than 1 A.

[A7] The semiconductor test apparatus (1) according to A6, wherein the first current (IL) is not more than 100 mA.

[A8] The semiconductor test apparatus (1) according to any one of A1 to A7, wherein the second voltage (VL) is not more than 100 V.

[A9] The semiconductor test apparatus (1) according to any one of A1 to A8, wherein the second current (IH) is not less than 1 A.

[A10] The semiconductor test apparatus (1) according to A9, wherein the second current (IH) is not less than 10 A.

[A11] The semiconductor test apparatus (1) according to any one of A1 to A10, wherein the semiconductor switching device (SW) has a breakdown voltage (VB1) of not less than 500 V.

[A12] The semiconductor test apparatus (1) according to any one of A1 to A11, wherein the semiconductor switching device (SW) includes a wide bandgap semiconductor.

[A13] The semiconductor test apparatus (1) according to any one of A1 to A12, wherein the semiconductor switching device (SW) includes a transistor of an insulated gate type.

[A14] The semiconductor test apparatus (1) according to A13, wherein the transistor is of a trench gate type.

[A15] The semiconductor test apparatus (1) according to any one of A1 to A14, further comprising: a semiconductor rectifier (D) that is electrically interposed between the second power supply (P2) and the second relay (R2).

[A16] The semiconductor test apparatus (1) according to A15, wherein the semiconductor rectifier (D) has a breakdown voltage (VB2) of not less than the second voltage (VL).

[A17] The semiconductor test apparatus (1) according to A16, wherein the breakdown voltage (VB2) of the semiconductor rectifier (D) is not less than the breakdown voltage (VB1) of the semiconductor switching device (SW).

[A18] The semiconductor test apparatus (1) according to A16 or A17, wherein the breakdown voltage (VB2) of the semiconductor rectifier (D) is not less than 500 V.

[A19] The semiconductor test apparatus (1) according to any one of A15 to A18, wherein the semiconductor rectifier (D) includes a wide bandgap semiconductor.

[A20] The semiconductor test apparatus (1) according to any one of A15 to A19, wherein the semiconductor rectifier (D) includes a Schottky barrier diode.

While the embodiment has been described in detail above, this is merely a specific example used to clarify the technical contents. The various technical ideas extracted from this Description can be combined as appropriate with each other without being limited by the order of description, the order of embodiments, etc., in the Description.

What is claimed is:

1. A semiconductor test apparatus comprising:
a first node portion to which one end of a semiconductor switching device is to be electrically connected;
a second node portion to which another end of the semiconductor switching device is to be electrically connected;
a first power supply for high voltage and low current that generates a first voltage and a first current;
a second power supply for low voltage and high current that generates a second voltage lower than the first voltage and a second current higher than the first current;
a first relay that has a withstand voltage of not less than the first voltage and is electrically interposed between the first node portion and the first power supply;
a second relay that has a withstand voltage of not less than the second voltage and is electrically interposed between the first node portion and the second power supply;
a third relay that has a withstand voltage of not less than the first voltage and is connected in parallel to the second relay; and
a fourth relay that has a withstand voltage of not less than the second voltage and is connected in parallel to the second power supply.

2. The semiconductor test apparatus according to claim 1,
wherein when a high-voltage/low-current test is performed, the first power supply is controlled to be in an on state, the second power supply is controlled to be in an off state, the first relay is controlled to be in a conducting state, the second relay is controlled to be in a nonconducting state, the third relay is controlled to be in a conducting state, and the fourth relay is controlled to be in a conducting state.

3. The semiconductor test apparatus according to claim 1,
wherein when a low-voltage/high-current test is performed, the first power supply is controlled to be in an off state, the second power supply is controlled to be in an on state, the first relay is controlled to be in a nonconducting state, the second relay is controlled to be in a conducting state, the third relay is controlled to be in a nonconducting state, and the fourth relay is controlled to be in a nonconducting state.

4. The semiconductor test apparatus according to claim 1,
wherein the first voltage is lower than a breakdown voltage of the semiconductor switching device.

5. The semiconductor test apparatus according to claim 1,
wherein the first voltage is not less than 500 V.

6. The semiconductor test apparatus according to claim 1,
wherein the first current is not more than 1 A.

7. The semiconductor test apparatus according to claim 6,
wherein the first current is not more than 100 mA.

8. The semiconductor test apparatus according to claim 1,
wherein the second voltage is not more than 100 V.

9. The semiconductor test apparatus according to claim 1,
wherein the second current is not less than 1 A.

10. The semiconductor test apparatus according to claim 9,
wherein the second current is not less than 10 A.

11. The semiconductor test apparatus according to claim 1,
wherein the semiconductor switching device has a breakdown voltage of not less than 500 V.

12. The semiconductor test apparatus according to claim 1,
wherein the semiconductor switching device includes a wide bandgap semiconductor.

13. The semiconductor test apparatus according to claim 1,
wherein the semiconductor switching device includes a transistor of an insulated gate type.

14. The semiconductor test apparatus according to claim 13,
wherein the transistor is a trench gate type.

15. The semiconductor test apparatus according to claim 1, further comprising:
a semiconductor rectifier that is electrically interposed between the second power supply and the second relay.

16. The semiconductor test apparatus according to claim 15,
wherein the semiconductor rectifier has a breakdown voltage of not less than the second voltage.

17. The semiconductor test apparatus according to claim 16,
wherein the breakdown voltage of the semiconductor rectifier is not less than the breakdown voltage of the semiconductor switching device.

18. The semiconductor test apparatus according to claim 16,
wherein the breakdown voltage of the semiconductor rectifier is not less than 500 V.

19. The semiconductor test apparatus according to claim 15,
wherein the semiconductor rectifier includes a wide bandgap semiconductor.

20. The semiconductor test apparatus according to claim 15,
wherein the semiconductor rectifier includes a Schottky barrier diode.
